(19) United States
(12) Patent Application Publication
(10) Pub. No.: US 2015/0372214 A1
(43) Pub. Date: Dec. 24, 2015

(54) COOLED COOLING AIR SYSTEM HAVING THERMOELECTRIC GENERATOR

(71) Applicant: General Electric Company, Schenectady, NY (US)

(72) Inventors: Kihyung Kim, Atlanta, GA (US); Barrett David Gardiner, Malta, NY (US)

(21) Appl. No.: 14/313,640

(22) Filed: Jun. 24, 2014

(51) Int. Cl. H01L 35/30

(52) U.S. Cl. CPC H01L 35/30

(57) ABSTRACT

Various embodiments include a cooled cooling-air system including: an inlet hot fluid conduit fluidly connected with a hot air source from a turbomachine; an inlet cold fluid conduit fluidly connected with a cold fluid source, the cold fluid source having a lower temperature than the hot air source; and a first thermoelectric generator fluidly connected with the inlet hot fluid conduit and the inlet cold fluid conduit, the first thermoelectric generator for cooling the inlet hot fluid conduit and simultaneously generating an electrical output.

### FIELD OF THE INVENTION

The subject matter disclosed herein relates to cooling air systems. Specifically, the subject matter disclosed herein relates to cooled cooling air systems for turbomachinery.

### BACKGROUND OF THE INVENTION

Cooled cooling air systems manage cooling air temperatures of turbomachine components (e.g., gas turbomachine components and/or steam turbomachine components) via an economizer or a reboiler that typically generates intermediate pressure (IP) steam. In order to effectively cool the cooling fluid, long steam/water lines are installed to provide for sufficient heat transfer. However, these long steam/water lines can be costly, create complex extraction scenarios, and occupy significant space.

### BRIEF DESCRIPTION OF THE INVENTION

Various embodiments include a cooled cooling-air system having: an inlet hot fluid conduit fluidly connected with a hot air source from a turbomachine; an inlet cold fluid conduit fluidly connected with a cold fluid (e.g., cold water or air) source, the cold fluid source having a lower temperature than the hot air source; and a first thermoelectric generator fluidly connected with the inlet hot fluid conduit and the inlet cold fluid conduit, the first thermoelectric generator for cooling the inlet hot fluid conduit and simultaneously generating an electrical output.

A first aspect includes a cooled cooling-air system having: an inlet hot fluid conduit fluidly connected with a hot air source from a turbomachine; an inlet cold fluid conduit fluidly connected with a cold fluid source, the cold fluid source having a lower temperature than the hot air source; and a first thermoelectric generator fluidly connected with the inlet hot fluid conduit and the inlet cold fluid conduit, the first thermoelectric generator for cooling the inlet hot fluid conduit and simultaneously generating an electrical output.

A second aspect includes a cooled cooling-air system having: an inlet hot fluid conduit fluidly connected with a hot air source from a turbomachine; an inlet cold fluid conduit fluidly connected with an ambient air source, the ambient air source having a lower temperature than the hot air source; a first thermoelectric generator fluidly connected with the inlet hot fluid conduit and the inlet cold fluid conduit, the first thermoelectric generator for cooling the inlet hot fluid conduit and simultaneously generating an electrical output; and a second thermoelectric generator fluidly connected with the inlet hot fluid conduit and the inlet cold fluid conduit, the second thermoelectric generator fluidly connected with the inlet hot fluid conduit and the inlet cold fluid conduit in parallel with the first thermoelectric generator.

A third aspect includes a system having: a gas turbomachine; and a cooled cooling-air system fluidly connected with the gas turbomachine, the cooled cooling-air system including: an inlet hot fluid conduit fluidly connected with a hot air source from the turbomachine; an inlet cold fluid conduit fluidly connected with a cold fluid source, the cold fluid source having a lower temperature than the hot air source; and a first thermoelectric generator fluidly connected with the inlet hot fluid conduit and the inlet cold fluid conduit, the first thermoelectric generator for cooling the inlet hot fluid conduit and simultaneously generating an electrical output.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIG. 1 shows a schematic view of a system according to various embodiments.

FIG. 2 shows a schematic view of a system according to various alternative embodiments.

It is noted that the drawings of the invention are not necessarily to scale. The drawings are intended to depict only typical aspects of the invention, and therefore should not be considered as limiting the scope of the invention. In the drawings, like numbering represents like elements between the drawings.

### DETAILED DESCRIPTION OF THE INVENTION

As indicated above, aspects of the invention provide for a cooled cooling-air system utilizing a thermoelectric generator. In particular embodiments, the cooled cooling-air system is designed to cool at least one of a casing cooling fluid, a rotor cooling fluid, a hot gas path cooling fluid, or a compressor discharge cooling fluid.

Thermoelectric generators work via the Seebeck effect, generating electricity via a temperature gradient between two fluids. Unlike dynamoelectric generators, thermoelectric generators are generally considered solid-state devices without moving parts, with the exception of fans and/or pumps to move fluid. In some cases, thermoelectric generators can be inverted to heat or cool fluid using electricity as an input.

The efficiency of a thermoelectric generator is dictated by the temperature gradient between the hot/cold fluid in the device. The greater the temperature gradient, the higher the efficiency of the generator.

According to various embodiments, a cooled cooling-air system includes at least one thermoelectric generator for cooling an input hot fluid, while simultaneously generating electricity via the interaction of that input hot fluid with an input cold fluid.

In the following description, reference is made to the accompanying drawings that form a part thereof, and in which is shown by way of illustration specific exemplary embodiments in which the present teachings may be practiced. These embodiments are described in sufficient detail to enable those skilled in the art to practice the present teachings and it is to be understood that other embodiments may be utilized and that changes may be made without departing from the scope of the present teachings. The following description is, therefore, merely exemplary.

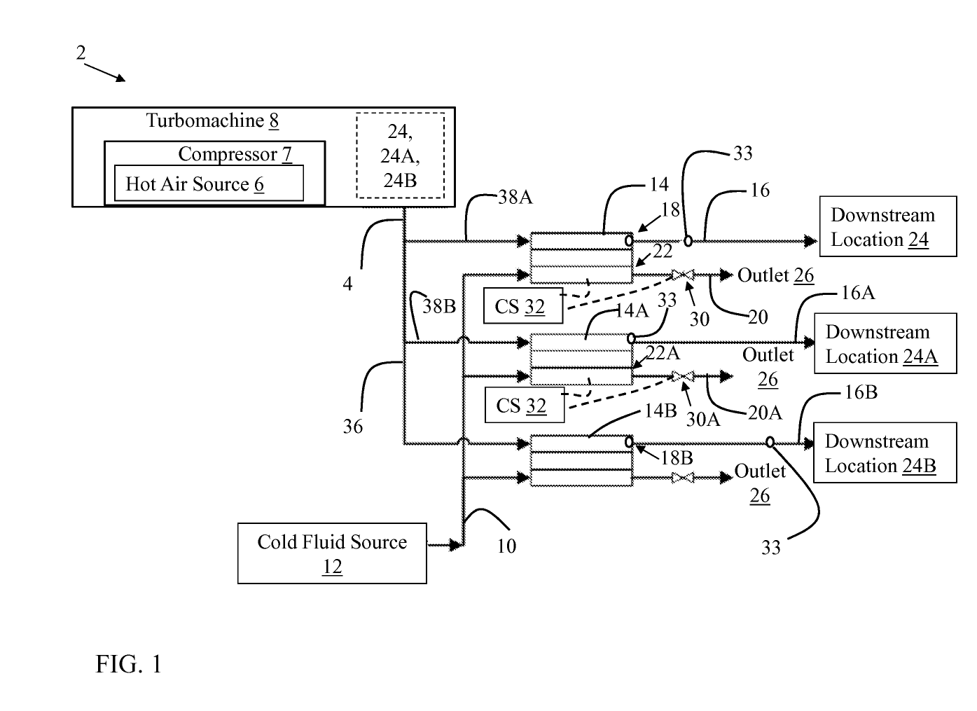

FIG. 1 shows a schematic depiction of a cooled cooling-air system 2 according to various embodiments. As shown, the cooled cooling-air system (or simply, CCA system) 2 can include an inlet hot fluid conduit 4 connected with a hot air source 6 from a turbomachine 8. According to various embodiments, the hot air source 6 in the turbomachine 8 includes cooling air from a turbomachine compressor 7 (e.g., gas turbomachine (GT) compressor), which is further cooled according to various embodiments for use as at least one of: a turbomachine casing cooling fluid, a turbomachine rotor cooling fluid, a turbomachine hot gas path cooling fluid or a turbomachine compressor discharge fluid. As described herein, the CCA system 2 can further cool cooling air for use in heat transfer within one or more components in turbomachine 8, e.g., a gas turbomachine. The CCA system 2 is configured to take inlet air from the hot air source 6 and cool that air for use in one or more downstream locations 24A, 24B, 24C, etc. in the turbomachine 8. It is understood, however, that the “hot air source” 6 can actually be a cooling fluid for cooling the compressor 7, and the term “hot” is relative to the “cold” fluid further described herein with respect to the CCA system 2.

The CCA system 2 can also include an inlet cold fluid conduit 10 fluidly connected with a cold fluid (e.g., cold air or cold water) source 12. The cold fluid source 12 has a lower temperature than the hot air source 6, in some cases by as much as approximately 700 degrees Fahrenheit (˜370 degrees Celsius) or more. In various embodiments, the cold fluid source 12 includes ambient air, and/or cold water from a steam turbine condenser. The CCA system 2 can further include a first thermoelectric generator 14 fluidly connected with the inlet hot fluid conduit 4 and the inlet cold fluid conduit 10. The first thermoelectric generator 14 can cool fluid passing from the inlet hot fluid conduit 4, and simultaneously generate an electrical output. As described herein, the thermoelectric generator 14 can be configured as a conventional thermoelectric generator to generate electricity from a temperature gradient between two fluids having a distinct temperature (e.g., temperature gradient as noted with respect to inlet hot fluid conduit 4 and inlet cold fluid conduit 10.

In various embodiments, the CCA system 2 can further include an outlet hot fluid conduit 16 fluidly connected with a hot outlet 18 of the first thermoelectric generator 14, and an outlet cold fluid conduit 20 fluidly connected with a cold outlet 22 of the first thermoelectric generator 14. The outlet hot fluid conduit 16 can carry exhaust hot fluid (cooled via heat transfer in the first thermoelectric generator 14) from the hot outlet 18 to a downstream location 24, e.g., a purge location. The outlet cold fluid conduit 20 can carry exhaust cold fluid (heated via heat transfer in the first thermoelectric generator 15) from the cold outlet 22 to a downstream location, e.g., an outlet 26 (which may include ambient and/or a recirculation location such as a condenser).

In some cases, the CCA system 2 further includes a valve 30 coupled with the outlet cold fluid conduit 20. In various embodiments, the valve 30 controls fluid flow through the outlet cold fluid conduit 20. In some cases, the valve 30 includes a butterfly valve or other conventional valve allowing for flow of cold fluid through the outlet cold fluid conduit 20 downstream of the valve 30.

In various embodiments, the CCA system 2 can include a control system (CS) 32 operably connected with the valve 30. The control system 32 can also be operably connected to the first thermoelectric generator 14, e.g., via wireless and/or hard-wired connection. The control system 32 can monitor an electrical output of the first thermoelectric generator 14, and control a flow of fluid through the outlet cold fluid conduit 20 based upon a temperature of the fluid at the hot fluid outlet 18 and/or in the outlet hot fluid conduit 16. In some cases, the control system 32 is configured (e.g., programmed) to compare the temperature of the fluid at the hot fluid outlet 18 (and/or in the outlet hot fluid conduit 16) to output temperature threshold, and modify the flow of fluid (e.g., cold fluid, via the valve 30) in response to the outlet hot fluid temperature deviating from the temperature threshold.

According to various embodiments, the control system 32 is coupled to one or more conventional temperature sensors 33 (connection may be hard-wired and/or wireless, not shown for clarity of illustration) within the outlet hot fluid conduit and/or proximate the first thermoelectric generator 14. The outlet hot fluid conduit 16 can carry the cooled cooling fluid from the hot fluid outlet 18 to a first downstream location 24, e.g., within the turbomachine 8. In some cases, where the temperature sensor(s) 33 indicate that the temperature of the outlet hot fluid from the thermoelectric generator 14 (or other thermoelectric generators 14A, 14B, etc. described herein) exceeds the threshold temperature (which may include a temperature range), the control system 32 can maintain or increase the amount of cold fluid flow (flow rate) through the outlet cold fluid conduit 20, e.g., by maintaining a position of the valve 30 or opening the valve 30 further, respectively. Where the temperature sensor(s) 33 indicate that the temperature of the outlet hot fluid from the thermoelectric generator 14 is below the threshold temperature (or range), the control system 32 can at least partially close the valve 30 in order to reduce the amount of cold fluid flow (flow rate) of the cold fluid through the outlet cold fluid conduit 20.

As illustrated in FIG. 1, in some embodiments, the CCA system 2 can further include a second thermoelectric generator 14A, which may be substantially similar to the first thermoelectric generator 14, and can be fluidly connected with the inlet hot fluid conduit 4 and the inlet cold fluid conduit 10, e.g., in a similar manner as the first thermoelectric generator 14. The second thermoelectric generator 14A can be configured to cool inlet hot fluid from the inlet hot fluid conduit 4 and simultaneously generate an additional electrical output (in addition to the first thermoelectric generator 14). As shown in this embodiment, the second thermoelectric generator 14A is fluidly connected with the inlet hot fluid conduit 4 and the inlet cold fluid conduit 10 in parallel with the first thermoelectric generator 14. That is, in some embodiments, the inlet hot fluid conduit 4 can include a main line 36 and a plurality of branches 38 extending from the main line 34, where the first thermoelectric generator 14 is fluidly connected with a first branch 38A of the plurality of branches 38 extending from the main line 34, and the second thermoelectric generator 14A is fluidly connected with a second branch 38B of the plurality of branches 28 extending from the main line 34, where the first branch 38A and the second branch 38B extend in parallel from the main line 34. In these embodiments, the CCA system 2 can further include a second outlet hot fluid conduit 16A fluidly connected with a hot outlet 18A of the second thermoelectric generator 14A, and an outlet cold fluid conduit 20A fluidly connected with a cold outlet 22A of the second thermoelectric generator 14A. The second outlet hot fluid conduit 16A can carry exhaust hot fluid (cooled via heat transfer in the second thermoelectric generator 14A) from the hot outlet 18A to a second downstream location 24A, e.g., a second location on the turbomachine 8 (or in some cases, a purge location). The outlet cold fluid conduit 20A can carry exhaust cold fluid (heated via heat transfer in the second thermoelectric generator 14A) from the cold outlet 22A to a downstream location, e.g., outlet 26 (which may include ambient and/or a condenser location). As noted herein, the downstream locations 24, 24A (and 24B) can be dictated by a cooling temperature of the exhaust fluid in the outlet hot fluid conduit 16, 16A (and 16B), respectively. That is, the downstream locations 24, 24A, etc. can be dictated by the temperature of the exhaust fluid on a dynamic basis, or may be predetermined based upon known cooling parameters in the turbomachine 8.

In some cases, the CCA system 2 further includes a second valve 30A coupled with the outlet cold fluid conduit 20A. In various embodiments, the second valve 30A allows fluid flow through the outlet cold fluid conduit 20A. In some cases, the valve 30A includes a butterfly valve or other conventional valve allowing for flow of cold fluid through the outlet cold fluid conduit 20A downstream of the valve 30A. In various embodiments, the control system 32 is operably connected with valve 30A, as well as the second thermoelectric generator 18A, and is configured to actuate valve 30A (similarly as described with respect to valve 30) and/or valve 30 based upon an exhaust fluid temperature of the outlet hot fluid exiting the outlets 18, 18A and/or 18B, and/or the temperature measured in the outlet hot fluid conduits) 16 and/or 16A (16B, etc.).

Control system 32 may be mechanically or electrically connected to first valve 30 and second valve 30A such that control system 32 may actuate first valve 30 and/or second valve 30A. Control system 32 may actuate first valve 30 and/or second valve 30A in response to determining that the temperature of the exhaust fluid at the outlet 18 and/or the outlet hot fluid conduit(s) 16 deviates from the predetermined threshold(s), e.g., exceeds the upper threshold as being too hot. Control system 32 may be a computerized, mechanical, or electro-mechanical device capable of actuating valves (e.g., valve 30 and/or valve 30A). In one embodiment control system 32 may be a computerized device capable of providing operating instructions to first valve 30 and/or second valve 30A. In this case, control system 32 may monitor the temperature(s) of the outlet hot fluid measured at temperature sensors 33, and provide operating instructions to first valve 30 and/or second valve 30A. For example, control system 32 may send operating instructions to open second valve 30A under certain operating conditions. In this embodiment, first valve 30 and/or second valve 30A may include electro-mechanical components, capable of receiving operating instructions (electrical signals) from control system 32 and producing mechanical motion (e.g., partially closing first valve 30 or second valve 30A). In another embodiment, control system 32 may include a mechanical device, capable of use by an operator. In this case, the operator may physically manipulate control system 32 (e.g., by pulling a lever), which may actuate first valve 30 and/or second valve 30A. For example, the lever of control system 32 may be mechanically linked to first valve 30 and/or second valve 30A, such that pulling the lever causes the first valve 30 and/or second valve 30A to fully actuate. In another embodiment, control system 32 may be an electro-mechanical device, capable of electrically monitoring (e.g., with sensors, e.g., temperature sensors 33) parameters indicating the temperature of the outlet hot fluid, and mechanically actuating first valve 30 and/or second valve 30A. While described in several embodiments herein, control system 32 may actuate first valve 30 and/or second valve 30A through any other conventional means.

According to various embodiments, the CCA system 2 can provide distinct temperature outputs at distinct outlet hot fluid conduits 16A, 16B, 16C, such that each downstream location 24A, 24B, 24C, etc., receives a distinct outlet hot fluid (used for cooling at those locations 24A, 24B, etc.), at a distinct temperature from the other locations. Each of the cooling streams (via outlet hot fluid conduits 16A, 16B, 16C) can be controlled independently by the control system 32 in order to meet a particular temperature threshold at each downstream location 24A, 24B, 24C.

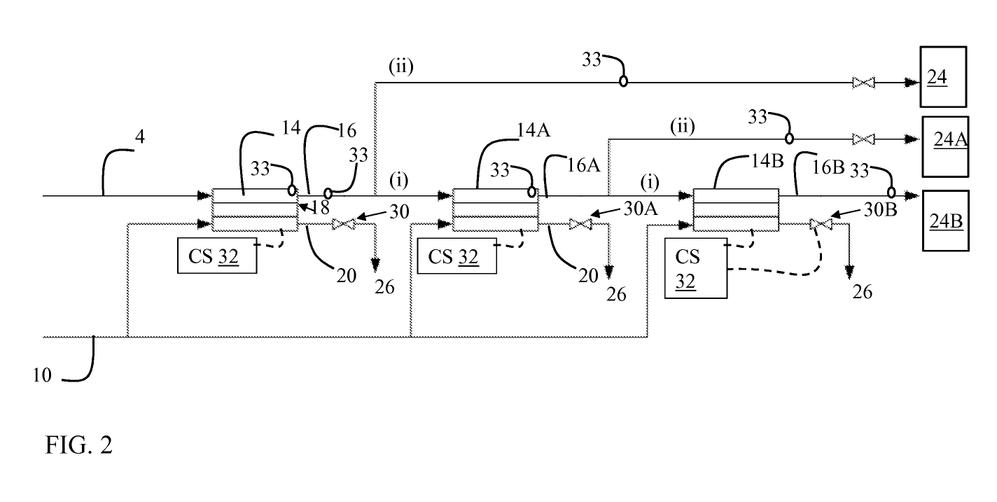

In various alternative embodiments, additional thermoelectric generators 14B, etc., can be connected in series (e.g., a second downstream of the first, etc.) with one or more thermoelectric generators (e.g., thermoelectric generator 14). In these embodiments, as shown in the schematic system diagram of FIG. 2, a second thermoelectric generator 14B can be fluidly connected with the outlet hot fluid conduit 16 from the first thermoelectric generator 14, downstream of the first thermoelectric generator 18. In various embodiments, the second thermoelectric generator 14B can cool outlet hot fluid from the outlet hot fluid conduit 16 and simultaneously generate an additional electrical output (in addition to the first thermoelectric generator 14). In some embodiments, as shown in FIG. 2, the outlet hot fluid conduits 16, 16A can include a first portion (i) fluidly connected to a downstream thermoelectric generator (e.g., 14B, 14C), and a second portion (ii) fluidly connected with a downstream location 24, e.g., a distinct cooling location or other location. Further, in the series configuration shown in FIG. 2, the cold fluid source 12 independently supplies cold fluid to each thermoelectric generator 14, 14A, 14B, etc., and that cold fluid is returned to another location in the system. Further, as described with respect to the parallel configuration in FIG. 1, in the series configuration in FIG. 2, the control system 32 is coupled, e.g., wirelessly and/or hard-wired with each of the valves 30, 30A, 30B, etc. (as illustrated with respect to valve 30B) and each of the plurality of temperature sensors 33.

In various embodiments, the series configuration of the CCA system in FIG. 2 can similarly generate distinct cooling fluid temperatures for distinct downstream locations 24A, 24B, 24C, as described with reference to FIG. 1. However, in the CCA system of FIG. 1, the first thermoelectric generator 14 produces the highest temperature outlet fluid (in conduit (ii)) flowing to downstream location 24, at the highest flow rate (Temp X, flow rate x), while the second thermoelectric generator 14A produces a lower outlet temperature fluid (in conduit (ii)) flowing to downstream location 24A at a lower flow rate (Temp Y, flow rate y), and the third thermoelectric generator 14B produces an even lower outlet temperature fluid (in outlet hot fluid conduit 16B) flowing to downstream location 24 at an even lower flow rate (Temp Z, flow rate z). In this case, Temp X>Temp Y>Temp Z.

In various embodiments, components described as being “coupled” to one another can be joined along one or more interfaces. In some embodiments, these interfaces can include junctions between distinct components, and in other cases, these interfaces can include a solidly and/or integrally formed interconnection. That is, in some cases, components that are “coupled” to one another can be simultaneously formed to define a single continuous member. However, in other embodiments, these coupled components can be formed as separate members and be subsequently joined through known processes (e.g., fastening, ultrasonic welding, bonding).

The terminology used herein is for the purpose of describing particular example embodiments only and is not intended to be limiting. As used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on”, “engaged to”, “connected to” or “coupled to” another element or layer, it may be directly on, engaged, connected or coupled to the other element or layer, or intervening elements or layers may be present. In contrast, when an element is referred to as being “directly on,” “directly engaged to”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Spatially relative terms, such as “inner,” “outer,” “beneath”, “below”, “lower”, “above”, “upper” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to an individual in the art are included within the scope of the invention as defined by the accompanying claims.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A cooled cooling-air system comprising:
an inlet hot fluid conduit fluidly connected with a hot air source from a turbomachine;
an inlet cold fluid conduit fluidly connected with a cold fluid source, the cold fluid source having a lower temperature than the hot air source; and
a first thermoelectric generator fluidly connected with the inlet hot fluid conduit and the inlet cold fluid conduit, the first thermoelectric generator for cooling the inlet hot fluid conduit and simultaneously generating an electrical output.

2. The cooled cooling-air system of claim 1, further comprising a second thermoelectric generator fluidly connected with the inlet hot fluid conduit and the inlet cold fluid conduit.

3. The cooled cooling-air system of claim 2, wherein the second thermoelectric generator is fluidly connected with the inlet hot fluid conduit and the inlet cold fluid conduit in parallel with the first thermoelectric generator.

4. The cooled cooling-air system of claim 1, further comprising:
an outlet hot fluid conduit fluidly connected with a hot outlet of the first thermoelectric generator; and
an outlet cold fluid conduit fluidly connected with a cold outlet of the first thermoelectric generator.

5. The cooled cooling-air system of claim 4, further comprising a second thermoelectric generator fluidly connected with the outlet hot fluid conduit and the outlet cold fluid conduit, downstream of the first thermoelectric generator, the second thermoelectric generator for cooling outlet hot fluid from the outlet hot fluid conduit and simultaneously generating an additional electrical output.

6. The cooled cooling-air system of claim 4, further comprising a valve coupled with the connector conduit for allowing fluid flow between the outlet hot fluid conduit and the outlet cold fluid conduit.

7. The cooled cooling-air system of claim 6, further comprising a control system operably connected with the valve, the control system configured to control a flow of fluid through the outlet cold fluid conduit based upon an outlet temperature of the outlet hot fluid from the first thermoelectric temperature.

8. The cooled cooling-air system of claim 7, wherein the control system further compares the temperature of the outlet hot fluid from the first thermoelectric generator to a temperature threshold, and modifies the flow of fluid in response to the temperature deviate from the temperature threshold.

9. The cooled cooling-air system of claim 1, wherein the cold fluid conduit is connected with ambient, and the cold fluid source is ambient air.

10. The cooled cooling-air system of claim 1, wherein the hot air source a compressor exhaust.

11. A cooled cooling-air system comprising:
an inlet hot fluid conduit fluidly connected with a hot air source from a turbomachine;
an inlet cold fluid conduit fluidly connected with an ambient air source, the ambient air source having a lower temperature than the hot air source;
a first thermoelectric generator fluidly connected with the inlet hot fluid conduit and the inlet cold fluid conduit, the first thermoelectric generator for cooling the inlet hot fluid conduit and simultaneously generating an electrical output; and
a second thermoelectric generator fluidly connected with the inlet hot fluid conduit and the inlet cold fluid conduit, the second thermoelectric generator fluidly connected with the inlet hot fluid conduit and the inlet cold fluid conduit in parallel with the first thermoelectric generator.

12. The cooled cooling-air system of claim 11, wherein the inlet hot fluid conduit includes a main line and a plurality of branches extending from the main line, wherein the first thermoelectric generator is fluidly connected with a first branch of the plurality of branches extending from the main line, and the second thermoelectric generator is fluidly connected with a second branch of the plurality of branches extending from the main line, wherein the first branch and the second branch extend in parallel from the main line.

13. The cooled cooling-air system of claim 11, further comprising:
an outlet hot fluid conduit fluidly connected with a hot outlet of the first thermoelectric generator; and
an outlet cold fluid conduit fluidly connected with a cold outlet of the first thermoelectric generator.

14. The cooled cooling-air system of claim 13, further comprising a valve coupled with the outlet cold fluid conduit allowing fluid flow through the outlet cold fluid conduit.

15. The cooled cooling-air system of claim 14, further comprising a control system operably connected with the valve, the control system configured to modify a flow of fluid through the outlet cold fluid conduit based upon an outlet temperature of the outlet hot fluid from the first thermoelectric generator.

16. The cooled cooling-air system of claim 15, wherein the control system further compares the temperature of the outlet hot fluid from the first thermoelectric generator to a temperature threshold, and modifies the flow of fluid in response to the temperature deviating from the temperature threshold.

17. The cooled cooling-air system of claim 11, wherein the hot air source includes a compressor exhaust.

18. A system comprising:
a gas turbomachine; and
a cooled cooling-air system fluidly connected with the gas turbomachine, the cooled cooling-air system including:
an inlet hot fluid conduit fluidly connected with a hot air source from the turbomachine;
an inlet cold fluid conduit fluidly connected with a cold fluid source, the cold fluid source having a lower temperature than the hot air source; and
a first thermoelectric generator fluidly connected with the inlet hot fluid conduit and the inlet cold fluid conduit, the first thermoelectric generator for cooling the inlet hot fluid conduit and simultaneously generating an electrical output.

19. The system of claim 18, further comprising:
an outlet hot fluid conduit fluidly connected with a hot outlet of the first thermoelectric generator; and
an outlet cold fluid conduit fluidly connected with a cold outlet of the first thermoelectric generator.

20. The system of claim 19, further comprising:
a valve coupled with the outlet cold fluid conduit allowing fluid flow through the outlet cold fluid conduit; and
a control system operably connected with the valve, the control system configured to modify a flow of fluid through the outlet cold fluid conduit based upon an outlet temperature of the outlet hot fluid from the first thermoelectric generator.
